(19) United States
(12) Patent Application Publication
(10) Pub. No.: US 2025/0140480 A1
(43) Pub. Date: May 1, 2025

(54) MULTILAYER CERAMIC ELECTRONIC COMPONENT AND MANUFACTURING METHOD THEREOF, AND CIRCUIT BOARD

(71) Applicant: TAIYO YUDEN CO., LTD., Tokyo (JP)

(72) Inventors: Shunya FUKUDA, Tokyo (JP); Takashi ASAI, Tokyo (JP); Michio OSHIMA, Tokyo (JP); Yoshinori SHIBATA, Tokyo (JP); Tomoaki NAKAMURA, Tokyo (JP); Keigo NAKAMURA, Toyko (JP)

(73) Assignee: TAIYO YUDEN CO., LTD., Tokyo (JP)

(21) Appl. No.: 18/984,186

(22) Filed: Dec. 17, 2024

Related U.S. Application Data
(63) Continuation of application No. PCT/JP2023/011445, filed on Mar. 23, 2023.

(30) Foreign Application Priority Data
Jun. 23, 2022 (JP) 2022-100764

(51) Int. Cl. H01G 4/232; H01G 4/008; H01G 4/12; H01G 4/30; H05K 1/18

(52) U.S. Cl. CPC H01G 4/2325; H01G 4/0085; H01G 4/1236; H01G 4/30; H05K 1/181; H05K 2201/10015

(57) ABSTRACT

A multilayer ceramic electronic component is equipped with a ceramic component and an external electrode. Said ceramic body has a plurality of internal electrodes that are stacked in the direction of a first axis, and an end surface that is perpendicular to a second axis that is orthogonal to the first axis, and from which said plurality of internal electrodes are drawn. Said external electrode includes a base layer that covers said end surface and is connected to said plurality of internal electrodes. Said plurality of internal electrodes and said base layer are made of a polycrystalline material mainly composed of copper. The average crystal grain size of the base layer described above is 1.2 times or more that of the plurality of internal electrodes described above.

### CROSS-REFERENCE TO RELATED APPLICATIONS

This application is a bypass continuation of International Application No. PCT/JP2023/011445, filed on Mar. 23, 2023, which claims the benefit of Japanese Application No. 2022-100764, filed on Jun. 23, 2022, in the Japanese Patent Office. All disclosures of the documents named above are incorporated herein by reference.

### TECHNICAL FIELD

The invention relates to a multilayer ceramic electronic component and the method for manufacturing the same, and to a circuit board.

### PRIOR ART

In recent years, due to increasing the frequencies of electronic devices to keep up with faster and higher capacity data communications, demand has increased for multilayer ceramic capacitors for higher frequencies. Multilayer ceramic capacitors for high frequencies need to have a low equivalent series resistance (ESR) and low losses at high frequency ranges (i.e. a high Q-value).

For multilayer ceramic capacitors meant for high frequencies, it is preferable, both from a viewpoint of improving the Q-value and from the viewpoint of reducing manufacturing costs, that both the internal electrodes and the external electrodes are made mainly of copper, which is a low-resistivity base metal. A configuration is disclosed in patent document 1 where copper is used for both the internal and external electrodes.

Specifically, with the technique disclosed in patent document 1, a sintered copper film is provided as an underlying layer for the external electrodes. With this technology, in order to control the occurrence of poor moisture resistance due to the intrusion of moisture into the sintered copper film, a metal plating film configured with 4 layers, which includes a precious metal plating film using gold, platinum, silver or palladium, is provided on the sintered copper film.

### PRIOR ART DOCUMENTS

### Patent Documents

[Patent Document 1] Japanese Unexamined Patent Publication No. 2004-055679 A

### OVERVIEW OF THE INVENTION

### Problem(s) to be Solved by the Invention

With the technology disclosed in patent document 1, manufacturing costs will be extremely high because precious metals such as gold, platinum, silver and palladium are used for the external electrodes. In addition, this technique cannot sufficiently prevent the plating solution from penetrating into the sintered copper film when the plating film is formed. The penetration of the plating solution into the sintered copper film can cause defects, such as a decrease in insulation resistance.

In view of such circumstances, an object of this invention is to provide a technique for improving the reliability of multilayer ceramic electronic components.

### Means for Solving the Problem(s)

In order to achieve the purpose described above, according to one aspect of this invention, a multilayer ceramic electronic component is equipped with a ceramic component and external electrodes.

Said ceramic body has a plurality of internal electrodes that are stacked in the direction of a first axis, and an end surface that is perpendicular to a second axis that is orthogonal to the first axis, and from which said plurality of internal electrodes are drawn.

Said external electrodes include a base layer that covers said end surface and is connected to said plurality of internal electrodes.

Said plurality of internal electrodes and said base layer are made of a polycrystalline material mainly composed of copper.

The average crystal grain size of the base layer described above is 1.2 times or more that of the plurality of internal electrodes described above.

The base layer for the external electrodes of this multilayer ceramic electronic component is made of a polycrystalline material with a large crystal grain size, so that the number of particle boundaries, which serve a paths for moisture penetration, can be reduced. This makes it difficult for moisture to penetrate into the base layer of the external electrodes in this multilayer ceramic electronic component, therefore improving moisture resistance and providing high reliability.

The base layer described above does not have to include a glass phase.

With this configuration, the conductivity of the base layer is not hindered by the influence of a glass phase, with high electrical resistance. In addition, crystal growth during firing will be promoted in a base layer that does not have a glass phase, making it more likely to turn into a polycrystalline body with large crystal particles.

The external electrodes described above may also include a plating layer that covers the base layer described above.

Such a plating layer may include a copper layer that adjoins to said base layer. In this situation, it is preferable for the average crystalline grain size of such a base layer to be larger than that of the copper layer.

Alternatively, the external electrodes described above, preferably include a sputtering layer that adjoins to said base layer, and where the average crystalline grain size of said base layer is larger than that of the sputtering layer.

With such configurations, it is possible to prevent the plating solution from penetrating into the base layer during the plating process that forms the plating layer. Therefore, with this configuration, an effect of improving the moisture resistance of the plating layer can be obtained without an accompanying influence of the plating solution.

Here, the value of the average crystalline grain size may be obtained by drawing a line segment of a predetermined length on a microstructure image obtained by capturing an image of a cross section of the base layer, the copper layer, or the sputtering layer at a predetermined magnification, and dividing the predetermined length by the number of crystal particles through which the line segment passes and the predetermined magnification

Said polycrystalline ceramic body may be mainly composed of CaxZrO₃ (where 0.9≤x≤1.15).

With this configuration, a multilayer ceramic electronic component can be obtained, capable of being suitably used at the high frequency range of 100 MHz to 2 GHz.

A circuit board according to one embodiment of this invention is used at a frequency range of 100 MHz to 2 GHz.

Such a circuit board possesses the multilayer ceramic electronic component and a mounting substrate.

Said mounting substrate has a mounting surface and a pair of connection electrodes arranged on the mounting surface and connected to the 1st and 2nd external electrodes of the multilayer ceramic electronic component by means of solder.

With a method for manufacturing a multilayer ceramic electronic component according to one embodiment of this invention, an unfired ceramic body is prepared, which has a plurality of internal electrodes stacked in the direction of a 1st axis and formed with a 1st conductive paste mainly composed of copper powder, and an end surface that is perpendicular to a 2nd axis that is orthogonal to the 1st axis and from which the plurality of internal electrodes are drawn.

An intermediate body is produced by forming a base layer, with a 2nd conductive paste mainly composed of a copper powder, on the end surface of the ceramic body.

The intermediate body is fired to form the base layer into a polycrystalline body having a crystalline grain size 1.2 times or more the average crystal grain size of the plurality of internal electrodes.

After firing, a plating layer is formed on the base layer of the intermediate body.

It is preferable for the 2nd conductive paste to not include silicon.

The copper powder constituting the 2nd conductive paste may have an average crystal grain size that is larger than the copper powder that constitutes the 1st conductive paste.

### Effect of the Invention

As described above, according to this invention, a technique for improving the reliability of multilayer ceramic electronic components can be provided.

### BRIEF DESCRIPTION OF THE DRAWINGS

FIG. 1 is a perspective view of a multilayer ceramic capacitor according to an embodiment of this invention.

FIG. 2 is a cross-section view taken along line A-A′ of said multilayer ceramic capacitor.

FIG. 3 is a cross-section view taken along line B-B′ of said multilayer ceramic capacitor.

FIG. 4 is an enlarged partial cross-section view of a region R of the multilayer ceramic capacitor in FIG. 2.

FIG. 5 is a flowchart showing a method of manufacture for said multilayer ceramic capacitor.

FIG. 6 is a diagram showing step S01 of said manufacturing method.

FIG. 7 is a diagram showing step S02 of said manufacturing method.

FIG. 8 is a side view of a circuit board that includes said multilayer ceramic capacitor.

### METHOD FOR CARRYING OUT THE INVENTION

An embodiment of this invention will be described below with reference to the drawings.

In the drawings, the X-, Y- and Z-axes are shown and are mutually orthogonal to each other. The X-, Y- and Z-axes are common to all drawings.

### [Configuration of Multilayer Ceramic Capacitor 10]

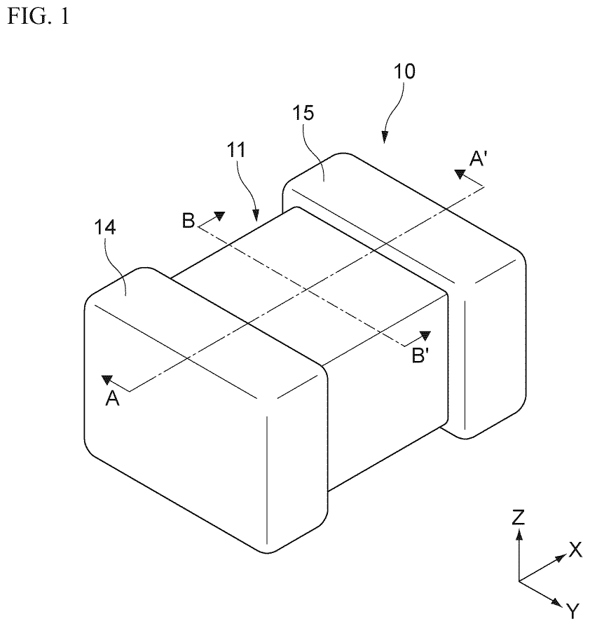

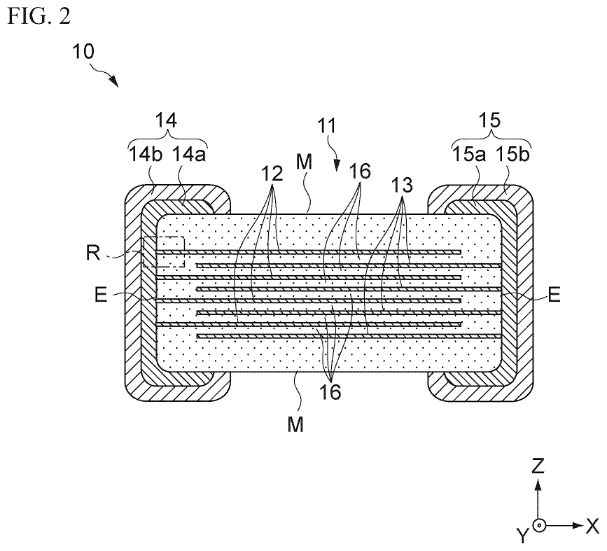

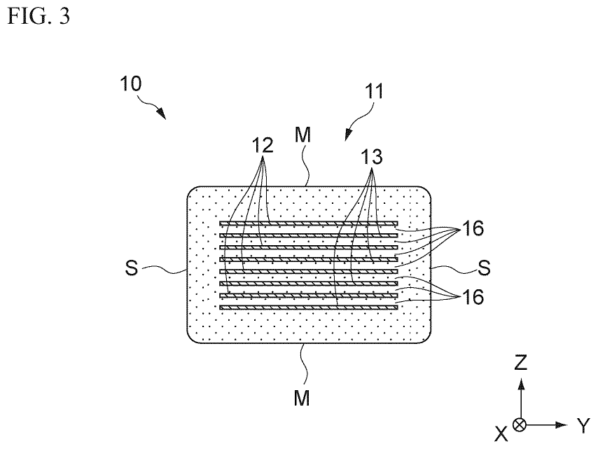

FIGS. 1 through 3 are views of a multilayer ceramic capacitor 10 according to an embodiment of this invention. FIG. 1 is a perspective view of multilayer ceramic capacitor 10. FIG. 2 is a cross-section view taken along line A-A′ of the multilayer ceramic capacitor in FIG. 1. FIG. 3 is a cross-section view taken along line B-B′ of the multilayer ceramic capacitor in FIG. 1.

multilayer ceramic capacitor 10 is equipped a ceramic component 11, a 1st external electrode 14 and a 2nd external electrode 15. The surfaces of ceramic body 11 are typically configured as a six-sided polygon, having a pair of end surfaces E perpendicular to the X-axis, a pair of side surfaces S perpendicular to the Y-axis, and a pair of main surfaces M perpendicular to the Z-axis.

The pair of end surfaces E, pair of side surfaces S and pair of main surfaces M of ceramic body 11 are all configured as flat surfaces. The flat surfaces according to this embodiment do not strictly have to be planar surfaces, as long as they are perceived as flat overall, and include, as examples, surfaces having minute irregularities or gently curving shapes.

Ceramic body 11 has edge sections that connect the pair of end surfaces E, pair of side surfaces S and pair of main surfaces M to each other. Ceramic body 11 may be provided with rounded edges by chamfering. Ceramic body 11 can be chamfered by a method such as barrel polishing.

Ceramic body 11 is formed from a dielectric ceramic. Ceramic body 11 has a plurality of 1st internal electrodes 12 and a plurality of 2nd internal electrodes 13, covered with a dielectric ceramic and stacked in the direction of the Z-axis. The plurality of internal electrodes 12 and 13 are sheet-shaped, extending along the X-Y plane, and are arranged alternately along the direction of the Z-axis.

This means that ceramic body 11 has an opposing area where internal electrodes 12 and 13 face each other in the direction of the Z-axis, and sandwich ceramic layer 16 between each other. 1st internal electrodes 12 are extended from the opposing area to one of the end surfaces, and connected to 1st external electrode 14. 2nd internal electrodes 13 are extended from the opposing area to the other end surface, and connected to 2nd external electrode 15.

With such a configuration, when a voltage is applied between 1st external electrode 14 and 2nd external electrode 15 in multilayer ceramic capacitor 10, the voltage is applied to the plurality of ceramic layers 16 in the opposing area of internal electrodes 12 and 13. As a result, a charge corresponding to the voltage between 1st external electrode 14 and 2nd external electrode 15 is stored in multilayer ceramic capacitor 10.

Multilayer ceramic capacitor 10 is configured so that it can be suitably used at the high frequency range of 100 MHz to 2 GHz, and can be used, for example, as a high frequency dielectric resonator or a filter. Multilayer ceramic capacitor 10 is configured so that a high Q-value (quality factor) can be achieved at a high frequency range.

Multilayer ceramic capacitor 10 needs to have small capacitance temperature changes so that it can exhibit stable performance at the high frequency range. Therefore, ceramic body 11 needs to use a dielectric ceramic where the dielectric constant changes little with temperature, so that the capacitance of each ceramic layer 16 changes little with temperature.

For this reason, ceramic body 11 is preferably formed of a polycrystalline material having a perovskite structure as a main phase, such as calcium (Ca) and zirconium (Zr), the dielectric constant of which changes little with temperature, and which is expressed by the general formula ABO₃ (where “A” indicates an A-site element, and “B” indicates a B-side element).

With the perovskite structure in the main phase of this polycrystalline body, Calcium (Ca) is the A-site element, and zirconium (Zr) is the B-site element. Specifically, the main phase of the polycrystalline material constituting ceramic body 11 can have a composition expressed as CaxZrO₃ (where 0.9≤x≤1.15).

For multilayer ceramic capacitor 10, internal electrodes 12 and 13 are composed as polycrystalline bodies the main component of which is copper (Cu), a base metal with low resistivity. Internal electrodes 12 and 13 form a sintered body integrated with ceramic layers 16 as ceramic body 11. As a result, for multilayer ceramic capacitor 10, the conductivity of internal electrodes 12 and 13 is high and the ESR (equivalent series resistance) is reduced, resulting in a high Q value.

1st external electrode 14 is arranged on the surface of ceramic body 11 and covers one of end surfaces E. 2nd external electrode 15 is arranged on the surface of ceramic body 11 and covers the other end surface E. External electrodes 14 and 15 sandwich ceramic body 11 and counter each other in the direction of the X-axis, functioning as terminals for multilayer ceramic capacitor 10.

External electrodes 14 and 15 extend internally along the direction of the X-axis from the pair of end surfaces E to the pairs of main surfaces M and side surfaces S, respectively, and are spaced apart from each other on the pair of main surfaces M and pair of side surfaces S. In this way, the cross sections of both external electrodes 14 and 15 are U-shaped along the X-Y plane and the X-Z plane.

1st external electrode 14 has a 1st base layer 14a and a 1st plating layer 14b. 1st base layer 14a constitutes the inner layer of 1st external electrode 14 and is connected to 1st internal electrode 12 on end surface E. 1st plating layer 14b constitutes the outer layer of 1st external electrode 14 and covers 1st base layer 14a.

2nd external electrode 15 has a 2nd base layer 15a and a 2nd plating layer 15b. 2nd base layer 15a constitutes the inner layer of 2nd external electrode 15 and is connected to 2nd internal electrode 13 on end surface E. 2nd plating layer 15b constitutes the outer layer of 2nd external electrode 15 and covers 2nd base layer 15a.

External electrodes 14 and 15 and base layers 14a and 15a are each formed as a polycrystalline body that is composed mainly of copper, a base metal with low resistivity, and are fired together with ceramic body 11 to form a dense sintered body with few voids. As a result, for multilayer ceramic capacitor 10, the conductivity of base layers 14a and 15a is high and the ESR (equivalent series resistance) is reduced, resulting in a high Q value.

Plating layers 14b and 15b in external electrodes 14 and 15 are formed using a wet plating method. Plating layers 14b and 15b can have single- or multi-layer structures, for example, a 2-layer structure, in order from the inside, a nickel layer and a tin layer, or a 3-layer structure having, in order from the inside, a copper layer, a nickel layer and a tin layer.

External electrodes 14 and 15 are formed so as to prevent moisture from penetrating end surface E of ceramic body 11. Specifically, in external electrodes 14 and 15, base layers 14a and 15a are covered with plating layers 14b and 15b in order to block moisture, and base layers 14a and 15a themselves are formed to prevent moisture from penetrating.

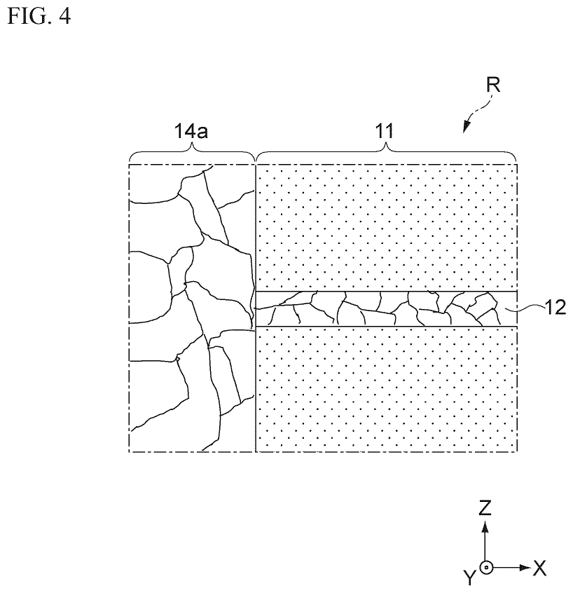

FIG. 4 is a partial cross-section view of multilayer ceramic capacitor 10, showing an enlarged view of the region R that is surrounded by a dashed line in FIG. 2. Region R is located in the section where 1st internal electrode 12 and 1st base layer 14a are connected. Note that the section where 2nd internal electrode 13 and 2nd base layer 15a are connected is configured in the same way as for region R.

In external electrodes 14 and 15, the base layers 14a and 15a are made of a polycrystalline material with a large crystal grain sizes, which reduces the number of particle boundaries, that serve a paths for moisture penetration. As a result, in multilayer ceramic capacitor 10, moisture is less likely to permeate base layers 14a and 15a, improving moisture resistance and providing high reliability.

In addition, it is not desirable for internal electrodes 12 and 13, which are made of a polycrystalline material mainly composed of copper, like the base layers 14a and 15a, to have a large crystal grain size, in order to ensure a high level of continuity along the X-Y plane. For this reason, it is necessary to maintain a small crystal grain size for internal electrodes 12 and 13 in multilayer ceramic capacitor 10.

Therefore, in a multilayer ceramic capacitor 10, the average crystal grain size of base layers 14a and 15a is at least 1.2 time, and preferably 1.35 times, the average crystal grain size of the internal electrodes. In doing this, it is possible for a multilayer ceramic capacitor 10 to prevent moisture from penetrating to base layer 14a and 15a, while not impairing the continuity of internal electrodes 12 and 13.

In addition, from standpoints such as mechanical strength, it is not desirable for the crystal grain size of base layers 14a and 15a of external electrodes 14 and 15 to be too large. Therefore, in multilayer ceramic capacitor 10, the average crystal grain size of base layers 14a and 15a is preferably no more than 1.75 times, and more preferably no more than 1.6 times, the average crystal grain size of internal electrodes 12 and 13.

The average crystal grain size of base layers 14a and 15a, and of internal electrodes 12 and 13, can be obtained from microstructure imaging of a cross-section. As an example, to get the average crystal grain size, microstructure imaging can be used on a cross-section of each part, exposed by scanning and grinding using a focused ion beam (FIB) and captured with a scanning ion microscope (SIM).

For example, to find the average crystal grain size, a line segment of a predetermined length is drawn on a microstructure image captured at a predetermined magnification, and the number of crystal particles that the line segment passes through is counted. In this way, the average crystal grain size can be determined by dividing the length of the line segment by the number of crystal particles it passes through and the magnification at which the microstructure image was captured. It is preferable to set the length of the line segment so that the number of crystal particles that it passes through is 20 or higher.

In addition, for external electrodes 14 and 15, it is preferable that base layers 14a and 15a do not include a glass phase. This prevents the conductivity of the base layer from being hindered by the influence of the glass phase, which has high electrical resistance. Furthermore, crystal growth during firing will be promoted in base layers 14a and 15a that does not have a glass phase, making them more likely to turn into polycrystalline bodies with large crystal grain sizes.

Moreover, for external electrodes 14 and 14, when plating layers 14b and 15b include a copper layer as the innermost layer adjacent to base layers 14a and 15a, it is preferable for the average crystal grain size of that copper layer to be smaller than the average crystal grain size of base layers 14a and 15a. This makes it easier to obtain a high bonding strength between plating layers 14b and 15b and base layers 14a and 15a.

### [Method of Manufacture for Multilayer Ceramic Capacitor 10]

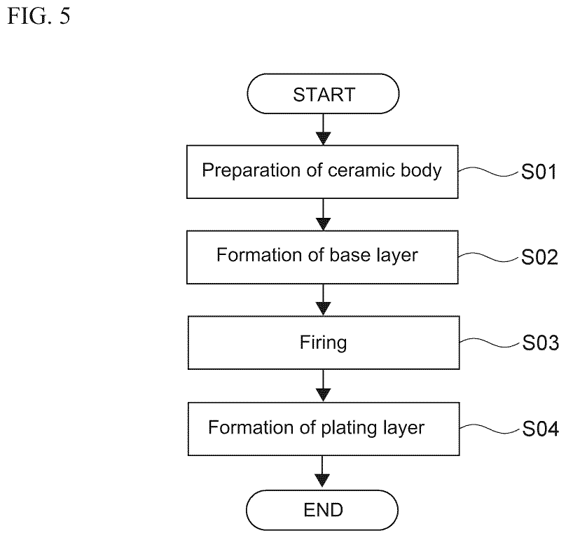

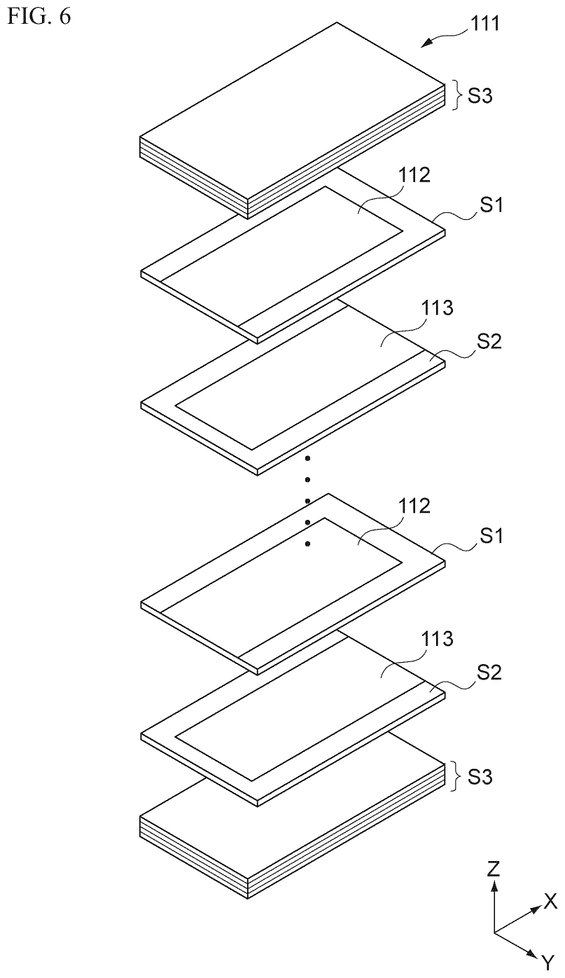

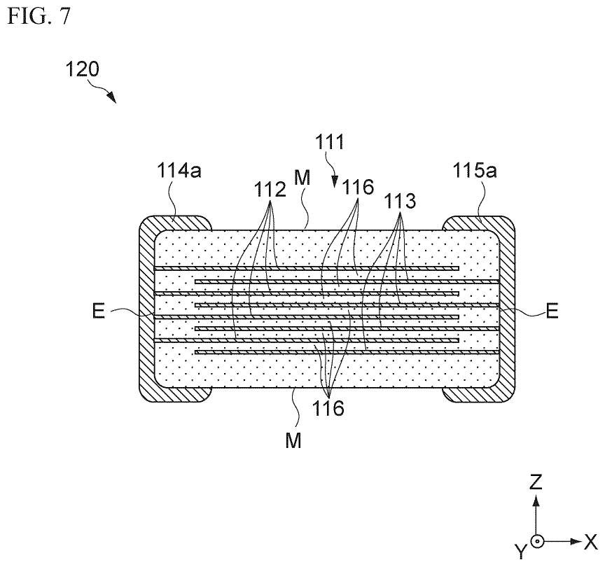

FIG. 5 is a flowchart showing a method of manufacture for multilayer ceramic capacitor 10 according to this embodiment. FIGS. 6 and 7 are diagrams showing the manufacturing process for multilayer ceramic capacitor 10. The method of manufacture for multilayer ceramic capacitor 10 will be described below following FIG. 5, with appropriate references to FIGS. 6 and 7.

### (Step S01: Preparation of the Ceramic Body)

In step S01, an unsintered ceramic body 111 is prepared. Ceramic body 111 corresponds to the state of ceramic body 11 before it is fired. Ceramic body 111 is obtained by stacking a 1st ceramic sheet S1, a 2nd ceramic sheet S2, and a 3rd ceramic sheet S3, as shown in FIG. 6.

Ceramic sheets S1, S2 and S3 are all formed of unsintered dielectric green sheets, the main component of which is a dielectric ceramic. Unsintered internal electrodes 112 and 113, corresponding to internal electrodes 12 and 13, are formed on ceramic sheets S1 and S2, respectively. Unsintered internal electrodes 112 and 113 are not formed on 3rd ceramic sheet S3.

Internal electrodes 112 and 113 are formed by applying a 1st conductive paste, the main component of which is copper powder, to ceramic sheets S1 and S2, in a predetermined pattern. Various printing methods can be used, such as screen printing, to apply the 1st conductive paste to ceramic sheets S1 and S2.

For ceramic body 111, ceramic sheets S1 and S2 are stacked alternately in layers, and 3rd ceramic sheets S3 are stacked above and below this in the direction of the Z-axis. Ceramic body 111 is integrated by pressing ceramic sheets S1, S2 and S3 together. The number of each of the ceramic sheets S1, S2 and S3 is not limited to the example in FIG. 6.

Although what is described above is an example where ceramic bodies 111 are produced one-by-one, in practice it is preferable to produce a plurality of ceramic bodies 111 at once. In other words, a laminated sheet, in which large ceramic sheets S1, S2 and S3 are stacked, is cut into individual pieces, so that a plurality of ceramic bodies 111 can be produced at once.

### (S02: Formation of the Base Layer)

In step S02, unsintered base layers 114a and 115a are formed on the unsintered ceramic body 111 produced in step S01. As a result, as shown in FIG. 7, an intermediate body 120 is obtained, in which both end surfaces E of unsintered ceramic body 111 are covered with unsintered base layers 114a and 115a.

Unsintered base layers 114a and 115a are formed by applying a 2nd conductive paste, the main component of which is copper powder, to predetermined regions of ceramic body 111. The 2nd conductive paste can be applied to ceramic body 111 by a dipping method or screen printing method, for example.

The average crystal grain size of the copper powder in the 2nd conductive paste forming base layers 114a and 115a is preferably larger than the average crystal grain size of the copper powder in the 1st conductive paste forming internal electrodes 112 and 113. As a result, it is easier to obtain base layers 14a and 15a having an average crystal grain size larger than those of internal electrodes 12 and 13 after firing.

In addition, it is preferable for the 2nd conductive paste forming base layers 114a and 115a to not contain silicon (Si). The absence of silicon, which easily forms a glass phase when incorporating other components during firing, in base layers 114a and 115a makes it easier to obtain base layers 14a and 15a that do not include a glass phase after firing. (S03: Firing)

In step S03, the intermediate body 120, obtained in step S02, is fired. As a result, ceramic body 111 and base layers 14a and 15a, which forms intermediate body 120, are sintered into a single body, so that ceramic body 111 becomes ceramic body 11, and base layers 114a and 115a become base layers 14a and 15a.

At this point, internal electrodes 12 and 13, as well as base layers 14a and 15a, are all polycrystalline bodies mainly composed of copper. Here, the average crystal grain size of base layers 14a and 15a, formed from the 2nd conductive paste, is at least 1.2 times the average crystal grain size of internal electrodes 12 and 13, formed from the 1st conductive paste.

Here, in a typical method, ceramic body 11 is fired first, and then the 2nd conductive paste is sintered onto the fired ceramic body 11 in order to form base layers 14a and 15a. In such a method, a glass component, such as a glass frit, needs to be added to the 2nd conductive paste in order to connect the base layers 14a and 15a to internal electrodes 12 and 13.

In this embodiment, ceramic body 11 and base layers 14a and 15a are fired simultaneously as a single body, so that the connections between internal electrodes 12 and 13 and base layers 14a and 15a are maintained during the sintering process. As a result, multilayer ceramic capacitor 10 can be configured so that base layers 14a and 15a do not include a glass phase.

The firing conditions in step S03 can be determined according to circumstances. In one example, the firing temperature is preferably lower than the melting point of copper (Cu) (1084° C.), which is the main component of internal electrodes 12 and 13, and base layers 14a and 15a, and can be set, for example, to 915° C.). In addition, the firing time can be set, for example, to 2.5 hours.

### (S04: Formation of the Plating Layer)

In step S04, plating layers 14b and 15b are formed on base layers 14a and 15a of the fired intermediate body 120. As a result, plating layers 14b and 15b, along with base layers 14a and 15a, form external electrodes 14 and 5, thereby obtaining ceramic body 11. Plating layers 14b and 15b can be formed by an electrolytic plating method.

In step S04, plating layers 14a and 15a are exposed to the plating solution, but because base layers 14a and 15a have large average crystal grain sizes, there are few particle boundaries that can serve as pathways for the plating solution to penetrate. As a result, it is possible to prevent a decrease in reliability in multilayer ceramic capacitor 10 caused by a plating solution penetrating end surface E of ceramic body 11.

### [Circuit Board 200]

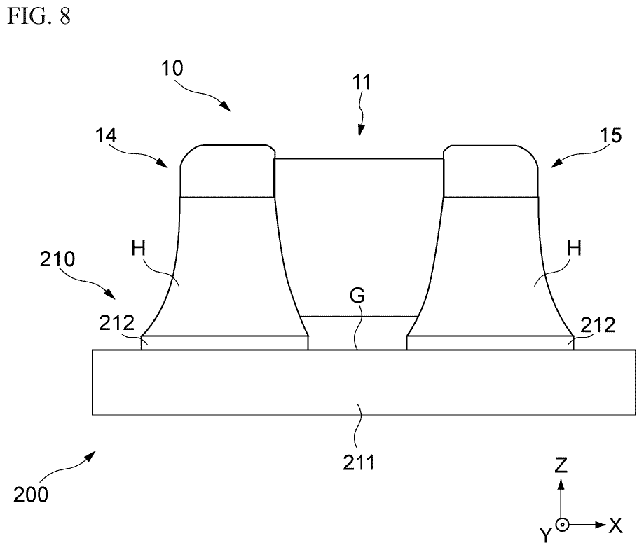

FIG. 8 is a side view of a circuit board 200 that includes a multilayer ceramic capacitor 10 according to this embodiment. Circuit board 200 according to this embodiment is typically circuit board used at a frequency range of 100 MHz to 2 GHz. However, circuit board 200 can be configured so that it can be suitably used at a variety of frequency ranges.

Circuit board 200 has a mounting substrate 210, on which multilayer ceramic capacitor 10 is mounted. Mounting substrate 210 has a base material 211 and a pair of connection electrodes 212. Base material 211 has a mounting surface G that extends along the X-Y plane and is perpendicular to the Z-axis. The pair of connection electrodes 212 are provided on mounting surface G of base material 211.

On circuit board 200, external electrodes 14 and 15 from multilayer ceramic capacitor 10 are respectively connected to the pair of connection electrodes 212 on mounting substrate 210 by solder H. As a result, multilayer ceramic capacitor 10 is affixed to and electrically connected to mounting substrate 210 on circuit board 200.

### Working Examples

Samples of multilayer ceramic capacitors were produced according to the above method of manufacture as examples 1, 2 and 3. In examples 1 and 3, the plating layer of the external electrodes had a 2-layer structure, with a nickel layer and a tin layer, from the inside in that order. In example 2, the plating layer of the external electrodes had a 3-layer structure, with a copper layer, a nickel layer and a tin layer, from the inside in that order.

The average crystal grain size for the polycrystalline bodies forming the base layers of the internal and external electrodes of the ceramic body was determined for examples 1, 2 and 3. Average crystal grain sizes of the internal electrodes and base layers were determined using microstructure imaging of the cross-sections captured by a scanning ion microscope, in the same way as described above.

In addition, Q value measurements and accelerated lifespan testing were performed to assess the samples according to examples 1, 2 and 3. Q values were measured at a frequency of 1 GHz and at a voltage of 1.0 V. In the accelerated lifespan testing, the temperature was set at 125° C. and the voltage at 300V, and the time until current leakage occurred was measured.

In addition, as a comparative example for the above embodiment, a 2nd conductive paste, mainly composed of copper powder, was baked onto the fired ceramic body to form a base layer, and a 2-layer plating layer, having a nickel layer and a tin layer, from the inside in that order, was formed on the base layer in order to produce a multilayer ceramic capacitor sample, and assessments were performed in the same banner as in examples 1, 2 and 3.

Table 1 shows the average crystal grain size of the internal electrodes and base layers from the samples according to examples 1, 2 and 3, and the comparative example. In all the samples according to examples 1, 2 and 3, the average crystal grain size of the base layers was at least 1.2 times those of the internal electrodes. On the other hand, for the sample according to the comparative example, the average crystal grain size of the base layers was smaller than that of the internal electrodes.

Table 1 also shows the results from measuring the Q values of the samples according to examples 1, 2 and 3, as well as the comparative example. All of the samples according to examples 1, 2 and 3 achieved a large Q value of at least 200. On the other hand, the sample according to the comparative example had a Q value of less than 200, which is thought to be due to the high electrical resistance of the base layer.

Furthermore, Table 1 shows the results from the accelerated lifespan testing on the samples according to examples 1, 2 and 3, as well as the comparative example. All of the samples according to examples 1, 2 and 3 achieved a high durability of at least 100 hours. On the other hand, the sample according to the comparative example lasted less than 100 hours, which is thought to be due to moisture penetrating into the base layer, causing current leakage to occur prematurely.

TABLE 1

| | Average crystal grain size (μm) | | | Accelerated |
|---|---|---|---|---|
| | Internal | | | lifespan |
| | electrode | Base layer | Q value | testing |
| Example 1 | 1.2 | 1.8 | 250-1100 | >100 hrs. |
| Example 2 | 1.2 | 1.9 | 300-1200 | >120 hrs. |
| Example 3 | 1.2 | 1.5 | 200-1050 | >100 hrs. |
| Comparative | 1.2 | 1.0 | 30-150 | >80 hrs. |
| example | | | | |

### Other Embodiments

Although an embodiment of this invention has been described above, the invention is not limited to said embodiment, and it goes without saying that various modifications can be made without departing from the main point of this invention.

For example, for multilayer ceramic capacitor 10, plating layers 14b and 15b may not be provided on external electrodes 14 and 15. In this case, external electrodes 14 and 15 may be configured such that another layer, such as a sputtering film, is provided on base layers 14a and 15a, or they may be configured with only the base layers 14a and 15a.

Furthermore, as long as internal electrodes 12 and 13 and base layers 14a and 15a are made of a polycrystalline material mainly composed of copper, multilayer ceramic capacitor 10 does not have to be configured for high frequencies. multilayer ceramic capacitor 10 may be configured to configured to achieve a high capacity by using, for example, a barium titanate-based material.

In addition, this invention is applicable not only for multilayer ceramic capacitor 10, but also for all multilayer ceramic electronic components having internal and external electrodes. In addition to multilayer ceramic capacitors, examples of multilayer ceramic electronic components to which this invention can be applied include chip varistors, chip thermistors, and laminated inductors.

### EXPLANATION OF SYMBOLS

10 Multilayer ceramic capacitor
11 Ceramic body
12, 13 Internal electrodes
14, 15 External electrodes
14a, 15a Base layer
14b, 15b Plating layer
16 Ceramic layer

1. A multilayer ceramic electronic component comprising: a ceramic body having a plurality of internal electrodes that are stacked in the direction of a first axis, and an end surface that is perpendicular to a second axis that is orthogonal to the first axis, and from which the plurality of internal electrodes are drawn;
an external electrode that includes a base layer that covers said end surface and is connected to said plurality of internal electrodes;
and where
said plurality of internal electrodes and said base layer are made of a polycrystalline material mainly composed of copper; and
the average crystal grain size of said base layer is 1.2 times or more that of said plurality of internal electrodes.

2. The multilayer ceramic electronic component according to claim 1 where
said base layer does not include a glass phase.

3. The multilayer ceramic electronic component according to claim 1 where
said external electrode further includes a plating layer that covers said base layer.

4. The multilayer ceramic electronic component according to claim 3 where
said plating layer includes a copper layer that adjoins to said base layer; and
the average crystalline grain size of said base layer is larger than that of said copper layer.

5. The laminated ceramic electronic component according to claim 1 where
said external electrode includes a sputtering layer that adjoins to said base layer; and
the average crystalline grain size of said base layer is larger than that of said sputtering layer.

6. The multilayer ceramic electronic component according to claim 4 where
the value of said average crystalline grain size is obtained by drawing a line segment of a predetermined length on a microstructure image obtained by capturing an image of a cross section of said base layer, said copper layer, or said sputtering layer at a predetermined magnification, and dividing said predetermined length by the number of crystal particles through which said line segment passes and said predetermined magnification.

7. The multilayer ceramic electronic component according to claim 1 where
said polycrystalline ceramic body is mainly composed of CaxZrO₃ (where 0.9≤x≤1.15).

8. A circuit board used in a frequency range of 100 MHz to 2 GHz comprising:
the multilayer ceramic electronic component according to claim 1; and
a mounting substrate having a mounting surface and a pair of connection electrodes arranged on said mounting surface and connected to said 1st and 2nd external electrodes of said multilayer ceramic electronic component by means of solder.

9. A method for manufacturing a multilayer ceramic electronic component that comprises:
preparing an unfired ceramic body having a plurality of internal electrodes stacked in the direction of a 1st axis and formed with a 1st conductive paste mainly composed of copper powder, and an end surface that is perpendicular to a 2nd axis that is orthogonal to said 1st axis and from which said plurality of internal electrodes are drawn;
producing an intermediate body by forming a base layer, with a 2nd conductive paste mainly composed of a copper powder, on said end surface of said ceramic body;
firing the intermediate body to form said base layer into a polycrystalline body having an average crystal grain size 1.2 times or more the average crystal grain size of said plurality of internal electrodes; and
forming a plating layer on said base layer of said intermediate body after firing.

10. The method for manufacturing a multilayer ceramic electronic component according to claim 9 where
said 2nd conductive paste does not include silicon.

11. The method for manufacturing a multilayer ceramic electronic component according to claim 9 where
the copper powder constituting said 2nd conductive paste has an average crystal grain size that is larger than the copper powder that constitutes said 1st conductive paste.

12. The multilayer ceramic electronic component according to claim 2 where
said external electrode further includes a plating layer that covers said base layer.

13. The laminated ceramic electronic component according to claim 2 where
said external electrode includes a sputtering layer that adjoins to said base layer; and
the average crystalline grain size of said base layer is larger than that of said sputtering layer.

14. The multilayer ceramic electronic component according to claim 5 where
the value of said average crystalline grain size is obtained by drawing a line segment of a predetermined length on a microstructure image obtained by capturing an image of a cross section of said base layer, said copper layer, or said sputtering layer at a predetermined magnification, and dividing said predetermined length by the number of crystal particles through which said line segment passes and said predetermined magnification.

15. The multilayer ceramic electronic component according to claim 2 where
said polycrystalline ceramic body is mainly composed of CaxZrO₃ (where 0.9≤x≤1.15).

16. A circuit board used in a frequency range of 100 MHz to 2 GHz comprising:
the multilayer ceramic electronic component according to claim 2; and
a mounting substrate having a mounting surface and a pair of connection electrodes arranged on said mounting surface and connected to said 1st and 2nd external electrodes of said multilayer ceramic electronic component by means of solder.

17. The method for manufacturing a multilayer ceramic electronic component according to claim 10 where
the copper powder constituting said 2nd conductive paste has an average crystal grain size that is larger than the copper powder that constitutes said 1st conductive paste.
